(19) United States
(12) Patent Application Publication
(10) Pub. No.: US 2006/0144618 A1
(43) Pub. Date: Jul. 6, 2006

(54) Fill plated structure of inner via hole and manufacturing method thereof

(75) Inventors: Chang Kyu Song, Kyunggi-do (KR); Tae Hoon Kim, Kyunggi-do (KR); Kyung O. Kim, Seoul (KR); Woo Young Lee, Pusan (KR); Jee Soo Mok, Cheongju-si (KR)

Correspondence Address: DARBY & DARBY P.C., P. O. BOX 5257, NEW YORK, NY, 10150-5257, US

(73) Assignee: Samsung Electro-Mechanics Co., Ltd., Kyunggi-do (KR)

(21) Appl. No.: 11/137,357

(22) Filed: May 24, 2005

(30) Foreign Application Priority Data
Dec. 30, 2004 (KR) 10-2004-0116801

(51) Int. Cl. H05K 1/11; H01K 3/10

(52) U.S. Cl. 174/266; 29/852; 29/830; 174/261

(57) ABSTRACT

A fill plated structure of an inner via hole, which includes an electroless plated layer formed on a copper clad laminate having an inner via hole formed therethrough, a first copper electroplated layer formed on the electroless plated layer on the copper clad laminate and formed on an inner wall of the via hole to form an belly portion having a belly shape, and a second copper electroplated layer formed on the first copper electroplated layer of a surface of the copper clad laminate and formed on upper and lower portions of the first copper electroplated layer of the inner wall of the via hole to fill the via hole; and a method of manufacturing the same.

### INCORPORATION BY REFERENCE

The present application claims priority under 35 U.S.C. §119 to Korean Patent Application No. 2004-116801 filed on Dec. 30, 2004. The content of the application is incorporated herein by reference in its entirety.

### BACKGROUND OF THE INVENTION

1. Field of the Invention

The present invention relates, generally, to a fill plated structure of an inner via hole and a manufacturing method thereof. More particularly, the present invention relates to a fill plated structure of an inner via hole, in which a first plated layer is formed in a belly shape on an inner wall of the via hole using a pulse-reverse plating process, and then reverse current is transformed to form a second plated layer on upper and lower portions of the first plated layer of the inner wall of the via hole so as to fill the via hole; and a method of manufacturing the same.

2. Description of the Related Art

Were it not for software, a computer would be nothing but a hard metal box, as in the term ‘hardware’. Similarly, lots of ICs (Integrated Circuits) having superb performance and various electronic components would be useless, too, if they were aimlessly gathered. Hence, in order to obtain electronic products operating in accordance with intended designs, the circuits and the components should be appropriately disposed, electrically connected to each other, and supplied with power. In this way, a base substrate on which electronic components are mounted and electrically connected is a printed circuit board (PCB).

Recently, while electronic components have advanced toward high density, high speed, miniaturization and multi-functionality, research into new packaging substrates able to correspond to system-in-packaging is under thorough study. Thus, various methods have been proposed to realize short lines and fine pitches for optimization of the properties of the components on the PCB.

Further, since heat generated from chips upon operation of the mounted components may damage the chips, designs for radiating portions of the substrate required to rapidly remove the generated heat so as to protect the chips from the heat must be provided.

FIG. 1 shows a PCB having via holes 11, 12, 13, 14 and 15 formed in various shapes.

As shown in FIG. 1, the via holes formed through the PCB are classified, on the basis of their uses and shapes, into an inner via hole 11 for circuit connection between inner layers, a blind via hole 12 for circuit connection between layers, a staggered via hole 13 having a stepped circuit connection passage, a stacked via hole 14 having a plurality of stacked via holes, and a through via hole 15 for circuit connection between outer layers.

FIGS. 2a to 2c sequentially show a process of manufacturing the inner via hole 11.

In FIG. 2a, a copper clad laminate (CCL) 20 having an insulating layer 21 and copper foil layers 22 on both surfaces thereof is machined by a drilling process, to form an inner via hole 23 therethrough.

In FIG. 2b, an electroless plating process and a copper electroplating process are performed on the CCL 20, to form a plated layer 24.

The reason why the electroless plating process precedes the copper electroplating process is that an inner wall of the drilled hole is formed of an insulating material, and copper electroplating by electrolysis cannot be performed thereon. Thus, the electroless plating process is first performed by deposition, and then the copper electroplating process is performed. In addition, since the electroless plated film, which is undesirably thin and has insufficient properties, cannot be used as it is, it should be further plated by the copper electroplating process.

In FIG. 2c, after the plated layer 24 is formed by the electroless plating and the copper electroplating, the inner via hole 23 is filed with ink 25 to protect the plated layer on the inner wall thereof, to complete an inner via hole 11.

The ink includes a liquid insulating material or a conductive paste as a mixture of metal particles and a resin.

Alternatively, the inner via hole 23 may be filled using a fill plating process, instead of the ink 25. In this case, however, the fill plating process may form a space B in the via hole 23, as shown in FIG. 3. This is because a current density is very high at the surface of the PCB, while it is relatively low in the via hole, and hence, the plated layer on an inner wall of the via hole is thinner than that on the surface of the substrate, upon copper electroplating.

FIGS. 4a to 4d sequentially show a process of forming a blind via hole 12.

In FIG. 4a, a RCC (Resin Coated Copper) 43 having a thickness of 0.1T or less is formed on a base substrate having an inner via hole 41 and an inner circuit layer 42.

If the thickness of the RCC 43 is larger than 0.1T, it is impossible to fill plate the blind via hole. Thus, the thickness is preferably limited.

Alternatively, an insulating layer may be used, instead of the RCC 43 of copper foil on one surface of the resin layer.

In FIG. 4b, a blind via hole 44 is formed using a YAG, UV or CO₂ laser.

The UV and YAG laser can be used to machine the copper foil layer and the insulating layer, while the CO₂ laser can be used to machine only the insulating layer. Thus, in the case of using the CO₂ laser, the portion of forming the blind via hole 44 is subjected to copper foil etching, to easily perform a laser process.

In FIG. 4c, the electroless plating process is performed to form a seed layer 45, after which a resist pattern 46 having an outer circuit pattern and a blind via hole pattern is formed on the seed layer 45 using a photographic etching process.

The photographic etching process serves to transcribe a circuit pattern printed on an artwork film onto a photosensitive dry film using ultraviolet rays.

In FIG. 4d, after the seed layer 45 and the resist pattern 46 are formed, an electroplated layer 47 is formed to obtain an outer circuit and fill plate the blind via hole 44.

In this regard, Japanese Patent Laid-open Publication No. 2004-214410 particularly discloses a process of fill plating a blind via hole using a plating resist pattern.

A plating growth procedure in the blind via hole 44 is shown in FIG. 5, in which the plated layer on the inner wall of the blind via hole 44 is formed faster than the surface plated layer constituting an outer circuit layer to fill the blind via hole 44.

The staggered via hole 13 and the stacked via hole 14 depend on the stacking forms of the inner via hole 11 and the blind via hole 12.

As mentioned above, the process of filling the inner via hole with the ink is disadvantageous because heat conductivity of the substrate is limited due to the ink, and also, the subsequent cap plating process is further required on upper and lower portions of the inner via hole filled with the ink. Thus, the above process becomes complicated.

As mentioned above, the process of fill plating the blind via hole is disadvantageous because the blind via hole has an exposed upper portion, unlike the inner via hole, and thus, limitations are imposed on the plating growth depth of the via hole upon fill plating.

Further, although the fill plating process of the blind via hole may form the plated layer on the inner wall of the hole faster than the surface plated layer constituting an outer circuit layer, the surface plated layer is formed at a predetermined thickness or more, thus additionally requiring a polishing process.

### SUMMARY OF THE INVENTION

Accordingly, the present invention has been made keeping in mind the above problems occurring in the related art, and an object of the present invention is to provide a fill plated structure of an inner via hole, which is advantageous because a substrate has high heat conductivity.

Another object of the present invention is to provide a method of manufacturing a fill plated structure of an inner via hole, which is advantageous because a plating process is simplified.

In order to accomplish the above objects, the present invention provides a fill plated structure of an inner via hole, comprising an electroless plated layer formed on a copper clad laminate having an inner via hole formed therethrough, a first copper electroplated layer formed on the electroless plated layer on the copper clad laminate and formed on an inner wall of the via hole to form a belly portion having a belly shape, and a second copper electroplated layer formed on the first copper electroplated layer on the copper clad laminate and formed on upper and lower portions of the first copper electroplated layer on the inner wall of the via hole to fill the via hole.

Further, the present invention provides a method of manufacturing a fill plated structure of an inner via hole, including the steps of forming a via hole through a copper clad laminate; forming an electroless plated layer on the copper clad laminate and an inner wall of the via hole; forming a first copper electroplated layer on the electroless plated layer formed on the copper clad laminate and the inner wall of the via hole; and forming a second copper electroplated layer on the first copper electroplated layer to fill plate the via hole.

Furthermore, the present invention provides a method of manufacturing a fill plated structure of an inner via hole, including the steps of preparing a base substrate having a plurality of circuit layers and a plurality of insulating layers; laminating an insulating layer on the base substrate and forming a via hole through the substrate for connection between outer layers; forming a seed layer on the insulating layer and an inner wall of the via hole and forming a resist pattern having an outer circuit pattern and a via hole pattern on the seed layer; and forming a first copper electroplated layer and a second copper electroplated layer on the seed layer having the resist pattern and the inner wall of the via hole to form an outer circuit pattern and to fill plate the via hole.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a sectional view showing conventional via holes formed in various shapes;

FIGS. 2a to 2c are sectional views sequentially showing a conventional process of filling an inner via hole with ink;

FIG. 3 is a sectional view showing an inner via hole plated according to a conventional fill plating process;

FIGS. 4a to 4d are sectional views sequentially showing a conventional process of fill plating a blind via hole;

FIG. 5 is an enlarged sectional view showing a conventional plating growth procedure in a blind via hole;

FIG. 6 is a sectional view showing a fill plated structure of an inner via hole, according to an embodiment of the present invention; and

FIGS. 7a to 7g are sectional views sequentially showing a process of fill plating an inner via hole, according to an embodiment of the present invention;

FIG. 8a is a waveform showing pulse and reverse currents used for first copper electroplating, according to an embodiment of the present invention;

FIG. 8b is a waveform showing pulse and reverse currents used for second copper electroplating, according to an embodiment of the present invention; and

FIGS. 9a to 9l are sectional views sequentially showing a fill plating process of a through via hole, according to another embodiment of the present invention.

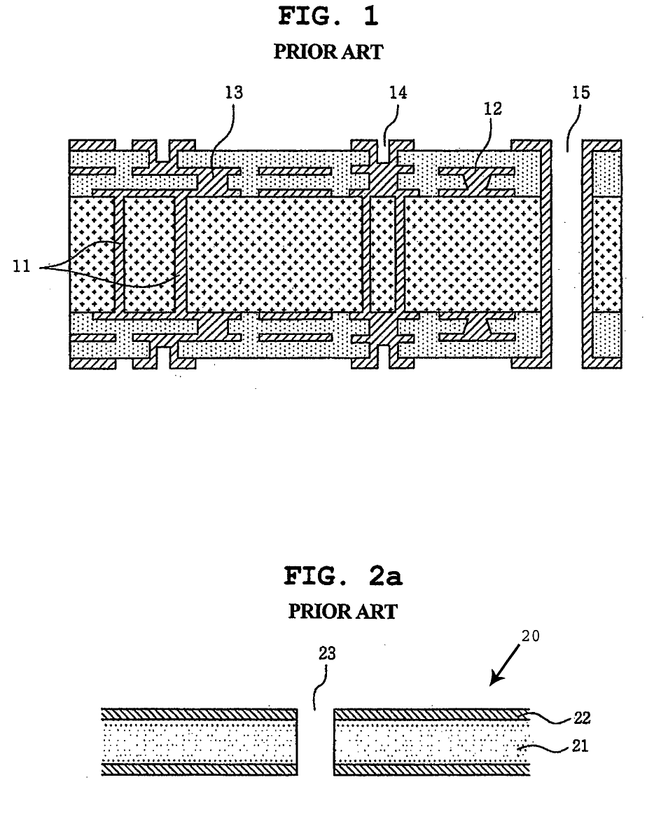

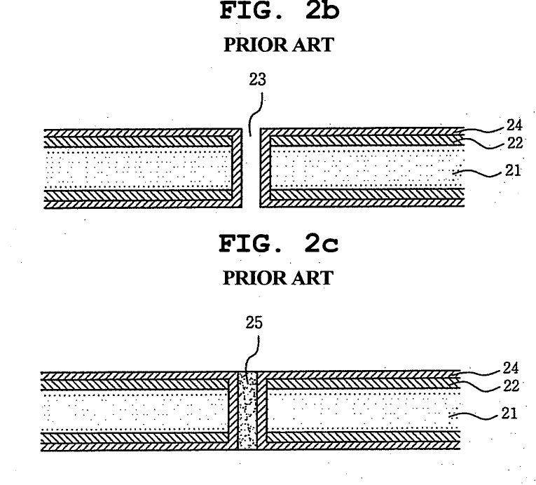

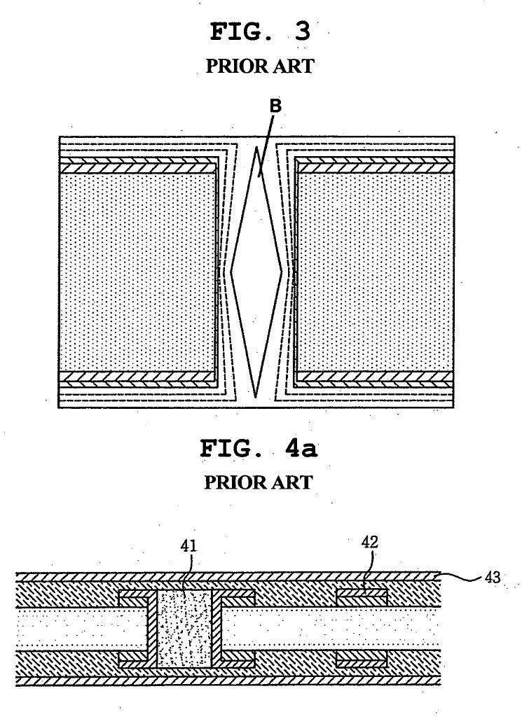

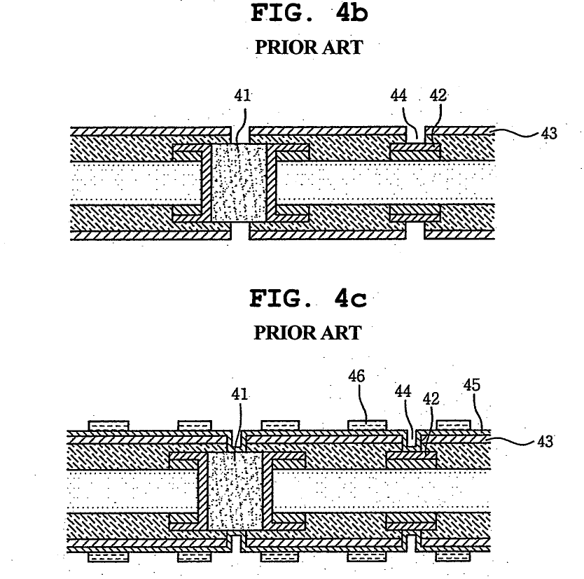

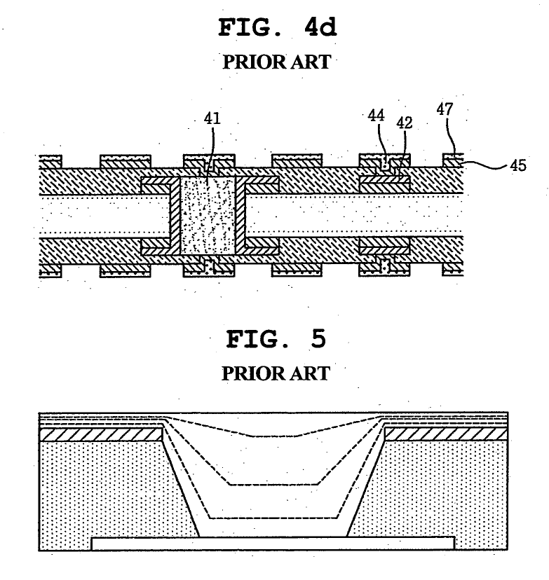

### DETAILED DESCRIPTION OF THE INVENTION

Hereinafter, a detailed description will be given of a fill plated structure of an inner via hole and a method of manufacturing the same according to the present invention, with reference to the appended drawings.

FIG. 6 shows a fill plated structure of an inner via hole, according to an embodiment of the present invention.

The fill plated structure of the inner via hole includes an electroless plated layer 63 formed on a CCL having an inner via hole for interlayer connection, a first copper electroplated layer 64 formed on the electroless plated layer 63, and a second copper electroplated layer 65 formed on the first copper electroplated layer 64.

That is, the electroless plated layer 63 is obtained by forming the inner via hole for interlayer electrical connection through the CCL having an insulating layer 61 and copper foil layers 62 formed on both surfaces thereof, and plating upper surfaces of the copper foil layers 62 and an inner wall of the via hole with a metal, such as copper, nickel or tin.

The first copper electroplated layer 64 is thinly formed on the electroless plated layer 63 of a surface of the CCL, and also, is multi-layered on the inner wall of the via hole to form an belly portion that protrudes radially and inwardly in a belly shape from the inner wall. An annular ridge of the belly portion defines an opening, in which a diameter of the opening is near to zero, and preferably equal to zero.

The second copper electroplated layer 65 is thinly formed on the first copper electroplated layer 64 on the CCL, and is also multi-layered on upper and lower portions of the first copper electroplated layer 64 on the inner wall of the via hole to fill the via hole.

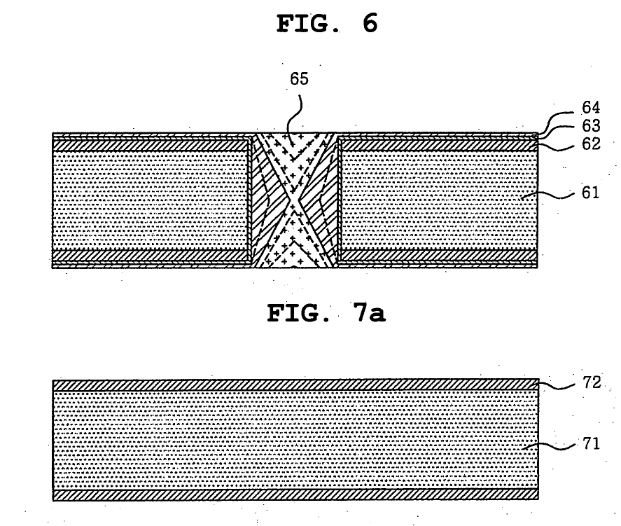

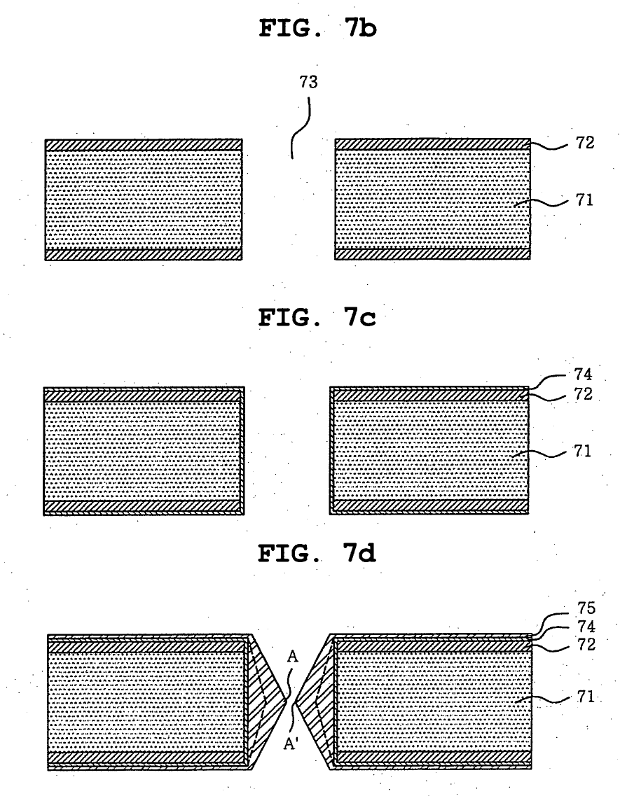

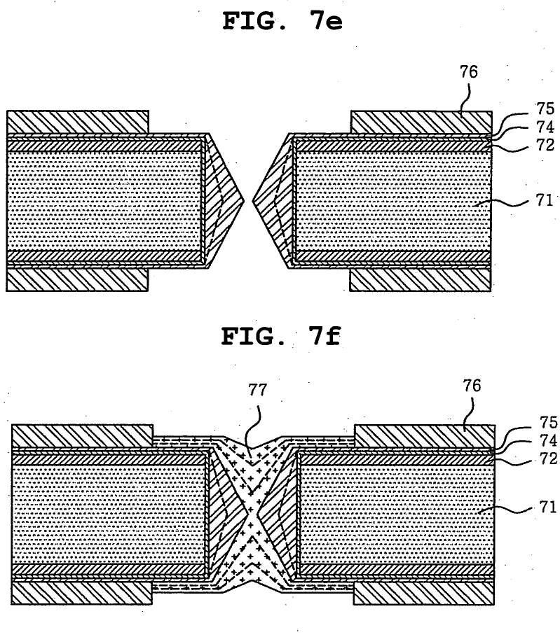

FIGS. 7a to 7g sequentially show a fill plating process of an inner via hole, according to the present embodiment of the invention.

In FIG. 7a, a CCL including an insulating layer 71 and copper foil layers 72 formed on both surfaces thereof is prepared.

The CCL is a base substrate for use in fabrication of a PCB and is a structure including copper foil 72 clad thinly on the insulating layer 71. Further, although the copper foil layer 72 has a thickness of about 18-70 μm, it may be 5, 7 or 15 μm thick depending on the fineness of a wire pattern.

In FIG. 7b, an inner via hole 73 is formed by a drilling process.

The process of forming the inner via hole 73 may be performed using a mechanical drill or a UV, YAG or CO₂ laser drill. Preferably, a mechanical drill is used to form the via hole at a previously set position. In addition, a deburring process and a desmearing process are carried out to remove various pollutants and impurities.

The deburring process functions to remove dust particles on the inner wall of the hole, and dust and fingerprints on the copper foil layer, as well as burrs on the copper foil layer generated upon drilling. Simultaneously, the deburring process serves to provide roughness to the surface of the copper foil layer so as to increase the adhesion of copper in the subsequent plating process.

The desmearing process functions to remove the resin, as a constitutive material of the substrate, melted by heat generated upon drilling and attached to the inner wall of the hole, because molten resin attached to the inner wall of the hole decreases the quality of the copper plated layer.

In FIG. 7c, after the inner via hole 73 is formed and the deburring and desmearing processes are performed, an electroless plated layer 74 is formed.

The electroless plating process schematically includes (1) cleaning (conditioning)→(2) soft-etching→(3) pre-dipping→(4) catalyst activating→(5) reducing→(6) electroless chemical copper plating→(7) acid treating. As such, the electroless plating process is used to form the conductive film on the resin wall of the drilled hole for copper electroplating in the hole. The electroless plated layer 74 is about 0.2-1.2 μm thick.

In FIG. 7d, a first copper electroplating process is performed on the electroless plated layer 74, so that a first copper electroplated layer 75 is formed in a belly shape in the inner via hole 73.

In this first copper electroplating process, instead of provision of direct current, pulse current and reverse current are alternately supplied to provide plating current. As a result of the provision of the resulting plating current, copper in a plating solution composed of an organic component including a brightener, a leveler and a carrier added to an inorganic chemical including copper (Cu), sulfuric acid (H₂SO₄) and hydrochloric acid (HCl), and a copper ion fed from an anode ball are deposited on a substrate to which a cathode is applied, by a redox reaction, resulting in a plated film.

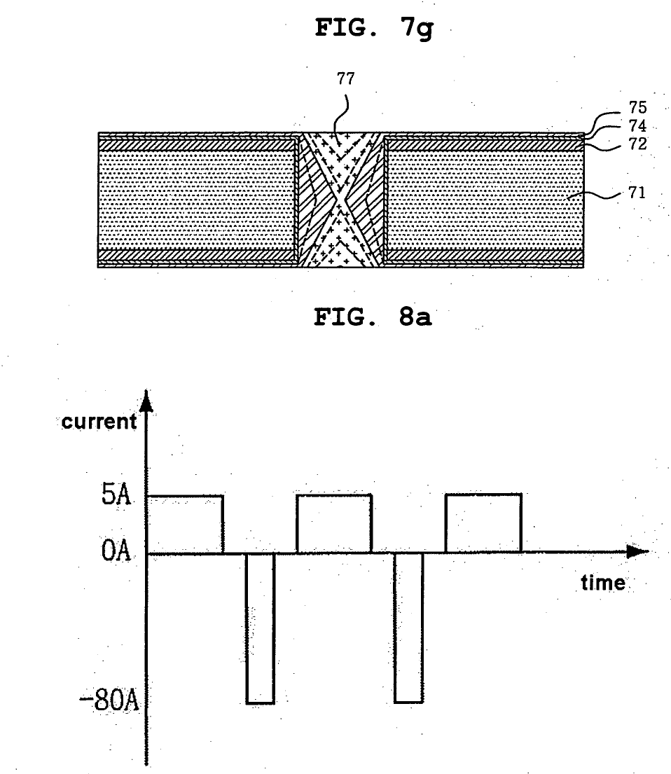

As shown in FIG. 8a, pulse current of 5 A and reverse current of high ampere, preferably 80 A or more, are alternately applied so that the first copper electroplated layer 75 is formed in a belly shape. To control the position of the annular ridge A and A′ of the belly portion of the first plated layer 75 upward and downward, the current is differently applied to the upper and lower portions of the CCL, and the plating time is controlled.

The first copper electroplating process is carried out until the diameter of the opening defined by the annular ridge A and A′ of the copper electroplated layer 75 on the inner wall of the via hole 73 is near to or equal to zero.

In the plating solution used for the first copper electroplating process, its constitutive components have the densities given in Table 1, below.

TABLE 1

| 1^{st} Copper | | |
|---|---|---|
| Electroplating Component | Density | |
| Cu | 30-50 | (g/L) |
| H₂SO₄ | 150-300 | (g/L) |
| HCl | 50-120 | (g/L) |
| Brightener | 5-20 | (g/L) |
| Leveler | 1-15 | (g/L) |
| Fe²⁺ | 10-20 | (g/L) |

In the plating solution, copper (Cu) functions to feed a copper ion and increase the conductivity of the plating solution, and Sulfuric acid (H₂SO₄) functions to control the conductivity of the plating solution and dissolve the anode ball. Also, hydrochloric acid (HCl) functions to adjust the reduction so as to control the formation speed of the plated film. In addition, the brightener acts to promote the plating process, and the leveler acts to inhibit the plating process.

Though iron (Fe²⁺) is added to promote provision of the copper ion, it may be omitted.

In FIG. 7e, after the first copper electroplated layer 75 is formed, a resist pattern 76 is formed on the first copper electroplated layer 75 so that the second copper electroplated layer 77 is mainly formed in the via hole while it is minimally formed on the surface of the substrate.

In the case where the inner via hole 73 has a diameter of 80 μm or less, the thickness of the surface plated layer may be controlled by polishing, and thus, the process of forming the resist pattern 76 may be omitted.

In FIG. 7f, a second copper electroplated layer 77 is formed.

In this second copper electroplating process, instead of provision of direct current, pulse current and reverse current are alternately supplied to provide plating current. As a result of the provision of the resulting plating current, copper in a plating solution composed of an organic component including a brightener, a leveler and a carrier added to an inorganic chemical including copper (Cu), sulfuric acid (H₂SO₄) and hydrochloric acid (HCl), and a copper ion fed from an anode ball are deposited on a substrate to which a cathode is applied, by a redox reaction, resulting in a plated film.

As is apparent from FIG. 8b, pulse current of 5 A and reverse current of high ampere, preferably about 160 A or more, are alternately applied so that the second copper electroplating process is performed on the first copper electroplated layer 75 to fill the via hole.

In the plating solution used for the second copper electroplating process, its constitutive components have the densities given in Table 2, below.

TABLE 2

| 2^{nd} Copper | | |
|---|---|---|
| Electroplating Component | Density | |
| Cu | 50-90 | (g/L) |
| H₂SO₄ | 60-200 | (g/L) |
| HCl | 40-60 | (g/L) |
| Brightener | 1-10 | (g/L) |
| Leveler | 1-10 | (g/L) |
| Fe²⁺ | 10-20 | (g/L) |

In FIG. 7g, after the second copper electroplated layer 77 is formed, the resist pattern 76 is removed by an etching process, and the leveling process is performed, thereby completing the process of fill plating the inner via hole.

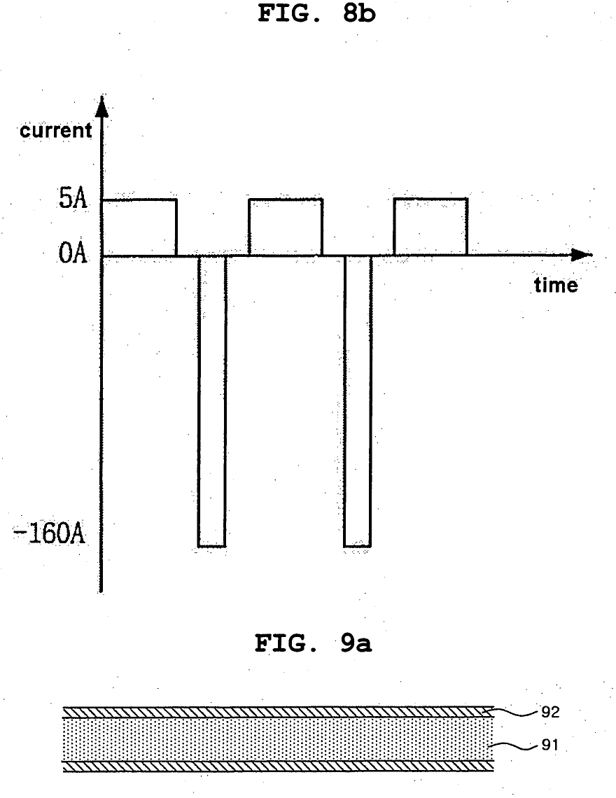

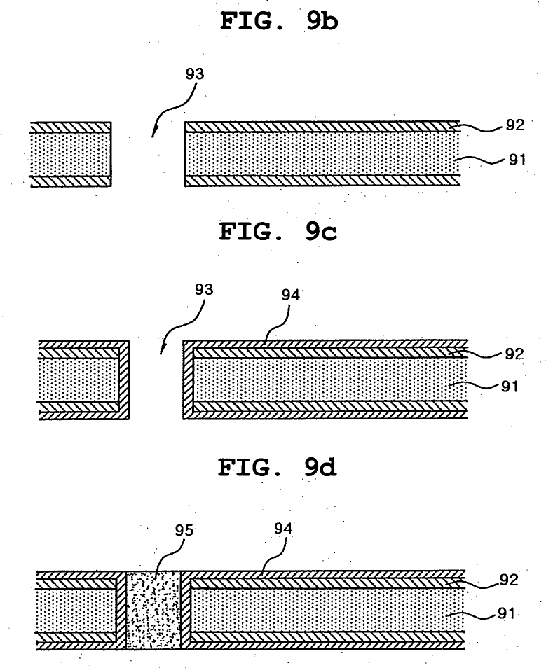

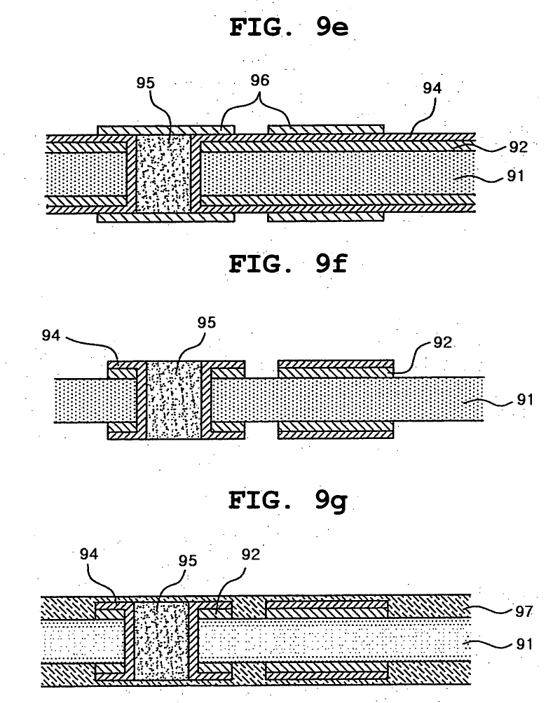

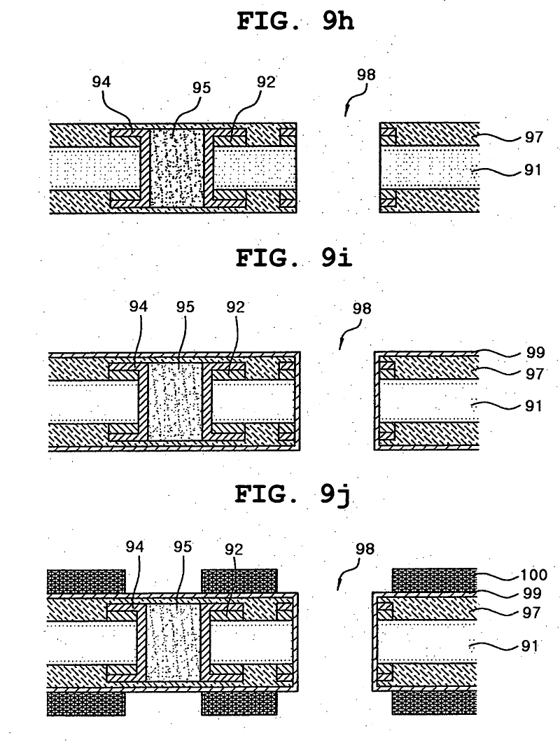

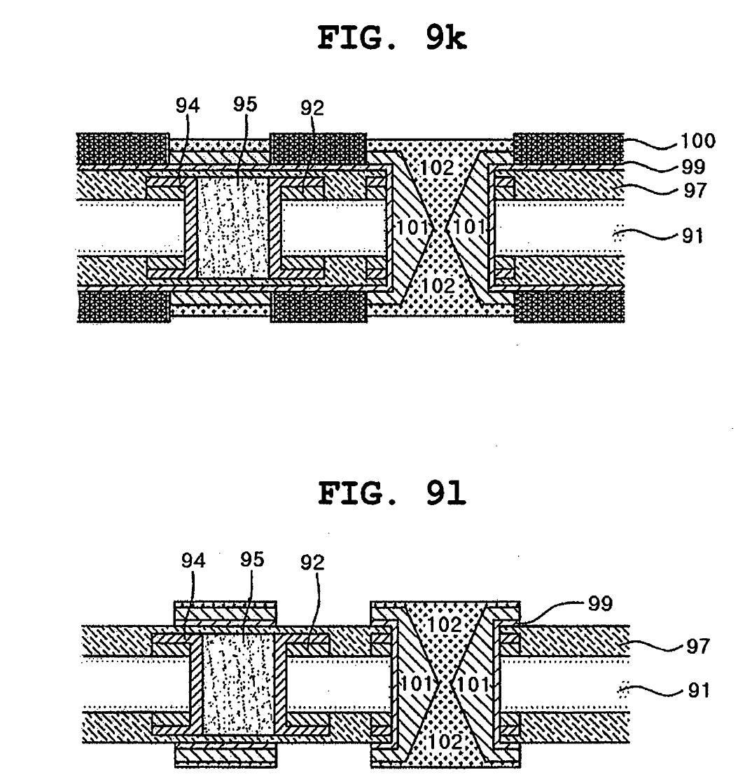

Turning now to FIGS. 9a to 9l, a process of fill plating a through via hole is sequentially shown, according to another embodiment of the present invention.

The through via hole is formed to electrically connect the outer layers of the PCB, and has the same form as the inner via hole.

In FIG. 9a, a CCL including an insulating layer 91 and copper foil layers 92 formed on both surfaces thereof is prepared.

In FIG. 9b, an inner via hole 93 is formed through the CCL by a drilling process.

The inner via hole 93 is used for interlayer electrical connection. After the drilling process, various pollutants and impurities generated upon forming the via hole are removed by deburring and desmearing processes.

In FIG. 9c, after the inner via hole 93 for interlayer electrical connection is formed through the CCL, the copper foil layer 92 and the inner via hole 93 are subjected to electroless plating and then copper electroplating, to obtain a plated layer 94.

The reason why the electroless plating precedes the copper electroplating is that the electroplating process requiring electricity cannot be carried out on the insulating layer of the CCL.

That is, as a pre-treatment to form the conductive film required for copper electroplating, an electroless plating process is performed, thus obtaining a thin electroless plated layer. However, electroless plating is disadvantageous because the process thereof is difficult and negates economic benefits. Hence, it is preferable that the conductive portion of the circuit pattern be formed by the copper electroplating process.

In FIG. 9d, the via hole 93 is filled with ink or is subjected to fill plating to form a fill plated layer 95, so as to protect the plated layer 94 formed on the inner wall of the via hole 93.

Although an insulating ink paste is generally used as the ink, a conductive paste may be used, depending on end purposes of the PCB. The conductive paste is composed mainly of metal selected from among Cu, Ag, Au, Sn, Pb and alloys thereof, and further includes an organic adhesive.

In FIG. 9e, after the via hole 93 is filled with the paste or is fill plated, an etching resist pattern 96 for use in formation of an inner circuit pattern is formed on the plated layer 94.

As such, the etching resist pattern 96 is formed by transcribing a circuit pattern printed on an artwork film onto the substrate. Although the transcribing process may be variously carried out, a manner of transcribing a circuit pattern printed on an artwork film to a photosensitive dry film using ultraviolet rays is employed.

The dry film having transcribed circuit pattern acts as the etching resist. In the case of performing an etching process using the above dry film as an etching resist, the portion of the plated layer 94 on which an etching resist pattern 96 is not formed is removed along with the portion of the copper foil layer 92 without an etching resist pattern 96 thereon, thus obtaining a base substrate having a predetermined inner circuit pattern, as shown in FIG. 9f.

Although the inner layer of the base substrate (that is, a copper foil layer having a circuit pattern of a base substrate) is structured into two layers, it may be multi-layered into four to six layers.

In FIG. 9g, an insulating layer 97 for interlayer insulation is formed on the base substrate to realize a build-up layer, which is formed of a synthetic material including a resin and a reinforcing agent.

In FIG. 9h, a through via hole 98 for electrical connection of outer circuit patterns is formed through the insulating layer 97 by a drilling process.

In FIG. 9i, a seed layer 99 is formed at a minimal thickness using electroless plating.

At this time, the electroless plating process is carried out using copper, nickel, tin, etc.

In FIG. 9j, after the seed layer 99 is formed, a resist pattern 100 having an outer circuit pattern and a via hole pattern is formed on the seed layer 99 using a photographic etching process.

In FIG. 9k, a first copper electroplated layer 101 and a second copper electroplated layer 102 are formed to fill plate the through via hole 98, and the outer circuit is formed.

The first copper electroplated layer 101 and the second copper electroplated layer 102 are formed by a pulse-reverse plating process. In the first and second copper electroplating processes, instead of provision of direct current, pulse current and reverse current are alternately supplied to provide plating current. As a result of the provision of the resulting plating current, copper in a plating solution composed of an organic component including a brightener, a leveler and a carrier added to an inorganic chemical including copper (Cu), sulfuric acid (H₂SO₄) and hydrochloric acid (HCl), and a copper ion fed from an anode ball are deposited on a substrate to which a cathode is applied, by a redox reaction, resulting in a plated film.

In the plating solution, copper (Cu) functions to feed a copper ion and increase the conductivity of the plating solution. Sulfuric acid (H₂SO₄) functions to control the conductivity of the plating solution and dissolve the anode ball. Also, hydrochloric acid (HCl) functions to adjust the reduction so as to control the formation speed of the plated layer. In addition, the brightener acts to promote the plating process, and the leveler acts to inhibit the plating process.

In the present embodiment, by applying pulse and reverse currents alternately to provide the plating current and changing the plating conditions, the first copper electroplated layer 101 is formed in a belly shape on an inner wall of the through via hole 98, and the second copper electroplated layer 102 is formed on upper and lower portions of the first copper electroplated layer 101, thus filling the through via hole 98.

As such, the plating conditions include, for example, densities of each plating component, reverse current intensities, and plating times.

In FIG. 9l, after the first copper electroplated layer 101 and the second copper electroplated layer 102 are formed, the resist pattern 100 is removed and the exposed seed layer 99 is etched, to complete the fill plating process of the through via hole 98.

As described above, the present invention provides a fill plated structure of an inner via hole and a method of manufacturing the same. According to the fill plating process of the via hole of the present invention, a pulse-reverse plating process is used to form the first copper electroplated layer and the second copper electroplated layer so as to fill plate the via hole. Thereby, heat conductivity of the substrate increases.

Further, the via hole, which has been conventionally filled with a paste or a liquid resin, is subjected to fill plating, whereby the subsequent cap plating process may be omitted. Therefore, the method of the present invention is advantageous because it is simplified and generates economic benefits.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A fill plated structure of an inner via hole, comprising:
an electroless plated layer formed on a copper clad laminate having an inner via hole formed therethrough;
a first copper electroplated layer formed on the electroless plated layer and on an inner wall of the via hole to form a belly portion having a belly shape; and
a second copper electroplated layer formed on the first copper electroplated layer and on upper and lower portions of the first copper electroplated layer on the inner wall of the via hole to fill the via hole.

2. The fill plated structure as set forth in claim 1, wherein the via hole is closed by the belly portion of the first copper electroplated layer.

3. The fill plated structure as set forth in claim 1, wherein the first copper electroplated layer is multi-layered.

4. The fill plated structure as set forth in claim 1, wherein the second copper electroplated layer is multi-layered.

5. A method of manufacturing a fill plated structure of an inner via hole, comprising the steps of:
forming a via hole through a copper clad laminate;
forming an electroless plated layer on the copper clad laminate and an inner wall of the via hole;
forming a first copper electroplated layer on the electroless plated layer; and
forming a second copper electroplated layer on the first copper electroplated layer to fill plate the via hole.

6. The method as set forth in claim 5, wherein the step of forming the first copper electroplated layer further comprises the step of forming a resist pattern using photographic etching having a via hole pattern.

7. The method as set forth in claim 5, wherein the step of forming the first copper electroplated layer further comprises the step of pulse-reverse plating to provide a belly shape on an inner wall of the via hole formed by the first copper electroplated layer.

8. The method as set forth in claim 5, wherein the step of forming the second copper electroplated layer further comprises the step of pulse-reverse plating to provide a copper electroplated layer on upper and lower portions of the first copper electroplated layer of the inner wall of the via hole.

9. A method of manufacturing a fill plated structure of an inner via hole, comprising the steps of:
preparing a base substrate having a plurality of circuit layers and a plurality of insulating layers;
laminating an insulating layer on the base substrate and forming a via hole through the substrate;
forming a seed layer on the insulating layer and an inner wall of the via hole and forming a resist pattern having an outer circuit pattern and a via hole pattern on the seed layer; and
forming a first copper electroplated layer and a second copper electroplated layer on the seed layer having the resist pattern and fill plating the via hole.

10. The method as set forth in claim 9, wherein the step of forming the first copper electroplated layer further comprises the step of pulse-reverse plating to provide a belly shape on an inner wall of the via hole formed by the first copper electroplated layer.

11. The method as set forth in claim 9, wherein the step of forming the second copper electroplated layer further comprises the step of pulse-reverse plating to provide a copper electroplated layer on upper and lower portions of the first copper electroplated layer of the inner wall of the via hole.
